(19) United States
(12) Patent Application Publication
(10) Pub. No.: US 2016/0111908 A1
(43) Pub. Date: Apr. 21, 2016

(54) POWER SUPPLY APPARATUS FOR ELECTRIC VEHICLE AND METHOD OF CONTROLLING THE SAME

(71) Applicant: HYUNDAI MOTOR COMPANY, Seoul (KR)

(72) Inventors: Chang Kiun KWARK, Seoul (KR); Dea Ki CHEONG, Yongin-si (KR)

(21) Appl. No.: 14/918,448

(22) Filed: Oct. 20, 2015

(30) Foreign Application Priority Data
Oct. 20, 2014 (KR) 10-2014-0141643

(51) Int. Cl. H02J 7/00; G01R 31/36

(52) U.S. Cl. CPC H02J 7/0054; G01R 31/3606

(57) ABSTRACT

A power supply system for an electric vehicle stably and efficiently supplies power to a connected external device when an ignition of an electric vehicle is turned off, and a method of controlling the same. A power supply apparatus of an electric vehicle may include a main battery, an auxiliary battery, a power converter for converting power from the main battery and recharging the auxiliary battery with the converted power, a port for recharging a connected external device by receiving power from the auxiliary battery when the ignition of the electric vehicle is turned off, and a battery sensor for monitoring a state of charge (SoC) of the auxiliary battery and starting the power converter according to the SoC.

### CROSS-REFERENCE TO RELATED APPLICATION

This application claims priority to and the benefit of Korean Patent Application No. 2014-0141643, filed on Oct. 20, 2014 with the Korean Intellectual Property Office, which is hereby incorporated by reference as if fully set forth herein.

### TECHNICAL FIELD

The present disclosure relates to an electric vehicle and, more particularly, to a power supply system capable of stably and efficiently supplying power to a connected external device when an ignition of an electric vehicle is turned off, and a method of controlling the same.

### BACKGROUND

In general, a vehicle uses a battery when being started, and includes a battery and an alternator to supply power to an interior lamp or electric devices such as an instrument panel and an air conditioner of the vehicle. In other words, when a starter motor is rotated to drive an engine at the time of starting the vehicle, the alternator connected to the engine through a fan belt is operated, thereby recharging the battery of the vehicle.

In an electric vehicle, a main battery and a motor function as an engine. In general, the main battery has a high voltage (for example, about 330 V). In addition, the electric vehicle includes an auxiliary battery in addition to the main battery. The auxiliary battery operates an electric switch to deliver power of the main battery corresponding to the high voltage to a motor control unit (MCU), or functions as a buffer for maintaining voltage balance in operations of various devices driven by electricity at low voltage (for example, 12 V) in the vehicle.

Recently, with popularization of a mobile device such as a smartphone, the mobile device has been frequently recharged in a vehicle using a port included in the vehicle, for example, a universal serial bus (USB) port. However, in the electric vehicle, when the ignition is turned off, power of the main battery is cut off, and thus power is not supplied to the USB port. As a result, the mobile device may not be recharged. In some vehicles, power of the auxiliary battery may be supplied to the USB port. However, in this case, there is concern that the auxiliary battery may be over discharged. Therefore, power may not be supplied to a motor controller, and the vehicle may not be operated.

### SUMMARY

An object of the present invention is to provide a power supply apparatus capable of supplying power to a particular port in an electric vehicle even when the ignition is turned off, and a method of controlling the same.

In particular, another object of the present invention is to provide a power supply apparatus capable of preventing an auxiliary battery from being over discharged when power is supplied to a particular port through the auxiliary battery, and a method of controlling the same.

Technical problems to be solved by the present invention are not limited to the above-mentioned technical problems, and other technical problems not mentioned herein may be clearly understood by those skilled in the art from description below.

To achieve these objects and other advantages and in accordance with the purpose of the invention, as embodied and broadly described herein, a power supply apparatus of an electric vehicle includes a main battery, an auxiliary battery, a power converter for converting power from the main battery and recharging the auxiliary battery with the converted power, a port for recharging a connected external device by power from the auxiliary battery when an ignition of the electric vehicle is turned off, and a battery sensor for monitoring a state of charge (SoC) of the auxiliary battery and starting the power converter according to the SoC.

In another aspect of the present invention, a method of supplying power of an electric vehicle includes detecting that an external device is connected to a port supplied with power through an auxiliary battery in a state in which an ignition of the electric vehicle is turned off, detecting a charging current by a detector of the port, monitoring an SoC of the auxiliary battery by a battery sensor when the detected charging current is greater than or equal to a first threshold value, and starting a power converter, which recharges the auxiliary battery using power of a main battery, by the battery sensor according to the SoC.

In another aspect of the present invention, a battery sensor includes a controller area network (CAN) transceiver for exchanging a signal with an external device, an SoC sensor for detecting an SoC of an auxiliary battery, and a controller for monitoring the SoC of the auxiliary battery when charging current information is received from a detector of a port when an ignition of an electric vehicle is turned off, and starting a power converter, which recharges the auxiliary battery using power of a main battery, according to the SoC of the auxiliary battery.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a block diagram illustrating an example of a configuration of a power supply apparatus of an electric vehicle according to an embodiment of the present invention;

FIG. 2 is a flowchart illustrating an example of an operation of supplying power of the electric vehicle according to an embodiment of the present invention; and

FIG. 3 is a flowchart illustrating an example of an operation of supplying power to a universal serial bus (USB) port of the electric vehicle according to an embodiment of the present invention.

### DETAILED DESCRIPTION

Hereinafter, a detailed description will be given of a power supply apparatus of an electric vehicle related to the present invention with reference to the drawings. The suffixes “module” and “unit” of elements of the electric vehicle herein are used for convenience of description and thus can be used interchangeably and do not have any distinguishable meanings or functions.

In an electric vehicle according to an embodiment of the present invention, when an external device is connected to a port that supplies power to external devices in a state in which an ignition is turned off, recharging is started using power of an auxiliary battery. In this instance, the auxiliary battery may be prevented from being over discharged using power of a main battery according to a state of the auxiliary battery. In addition, according to the present invention, when power supply through the port (for example, recharging of the connected external device) is completed, completion may be reported to the outside through a telematics system.

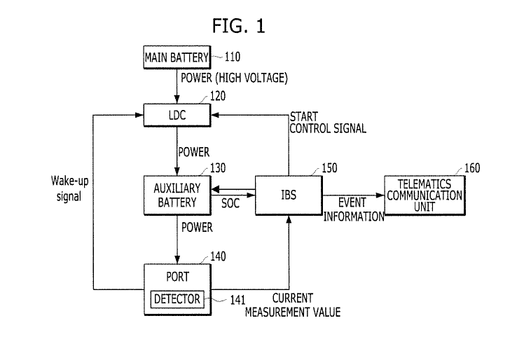

The above-described configuration of the power supply apparatus according to the present invention will be described with reference to FIG. 1.

FIG. 1 illustrates an example of the configuration of the power supply apparatus of the electric vehicle according to an embodiment of the present invention.

FIG. 1 illustrates components necessary to stably supply power to a particular port in the electric vehicle according to the present invention in a state in which the ignition is turned off. Even though the electric vehicle further includes various components including a motor, only components related to the present invention are illustrated herein.

Referring to FIG. 1, a main battery 110, a power converter (for example, a low direct current (DC)-DC converter (LDC)) 120, an auxiliary battery 130, a port 140, a battery sensor (for example, an intelligent battery sensor (IBS)) 150, and a telematics communication unit 160 participate in power supply according to the present invention. Hereinafter, the respective components will be described in more detail.

First, the main battery 110 supplies power to a motor which is the most significant in an electric vehicle driving system, and supplies power to various devices in the vehicle driven by electricity after the vehicle is started. In general, the main battery 110 has a high voltage (for example, about 330 V).

The power converter 120 may convert the voltage of the main battery 110 into a low voltage to recharge the auxiliary battery 130. The power converter 120 may be wired with a detector 141 of the port 140. The detector 141 may deliver a wake-up signal through wiring to wake up the power converter 120 in a state in which the ignition of the electric vehicle is turned off, which will be described below in more detail.

As described in the foregoing, the auxiliary battery 130 operates an electric switch to deliver power of the main battery 110 corresponding to the high voltage to a motor control unit (MCU), or functions as a buffer for maintaining voltage balance in operations of various devices driven at low voltage (for example, 12 V) in the vehicle. In addition, the auxiliary battery 130 supplies power to the port 140 in a state in which the ignition is turned off. For example, B+ line of the auxiliary battery 130 may be connected to the port 140 to supply regular power.

The port 140 functions as a means for connection to an external device. In this way, power may be delivered to the connected external device, and data exchange may be performed depending on configuration. Examples of the port 140 may include a universal serial bus (USB) port. The port 140 includes the detector 141, and the detector 141 may determine whether recharging of the external device is in progress/completed by measuring a current supplied to the external device connected through the port 140. For example, a general smartphone consumes a charging current of 1 A, and a tablet personal computer (PC) consumes a charging current of 2 A. Thus, recharging may be determined to be in progress when a particular current value (for example, 100 mA) or more is maintained for a certain period of time or more. Otherwise, recharging may be determined to be completed.

Subsequently, the battery sensor 150 may receive information about a state of charge (SoC) from the auxiliary battery 130, determine whether to start the power converter 120 based on the received information, and deliver a start control signal to the power converter 120. For example, when the SoC of the auxiliary battery 130 is 85% or less, the power converter 120 may be started. In this case, the auxiliary battery 130 may be recharged by the converted power from the power converter 120, and at the same time the auxiliary battery 130 may recharge the external device by the power stored therein. In addition, upon receiving a charging current measurement value from the detector 141 to determine that recharging of the external device connected to the port 140 is completed, the battery sensor 150 may report the determination as event information to the telematics communication unit 160. Depending on configuration, instead of the charging current measurement value, the detector 141 may deliver only information indicating that recharging is in progress or recharging is completed to the battery sensor 150.

The telematics communication unit 160 may deliver a signal corresponding to the event information to a predetermined device or contact information according to the event information received from the battery sensor 150. For example, when recharging of the device through the USB port is completed, a text message saying “Recharging of the device connected to the USB port in the electric vehicle has been completed.” may be transmitted to a number registered by a user through the telematics communication unit 160.

Although not illustrated, the battery sensor 150 may include an SoC sensor for detecting the SoC of the auxiliary battery, a controller area network (CAN) transceiver for communication with another component, and a controller for controlling the SoC and the CAN transceiver therein.

Hereinafter, a description will be given of an operation of supplying power to the port in the electric vehicle, the ignition of which is turned off, through a power supply system having the above-described configuration.

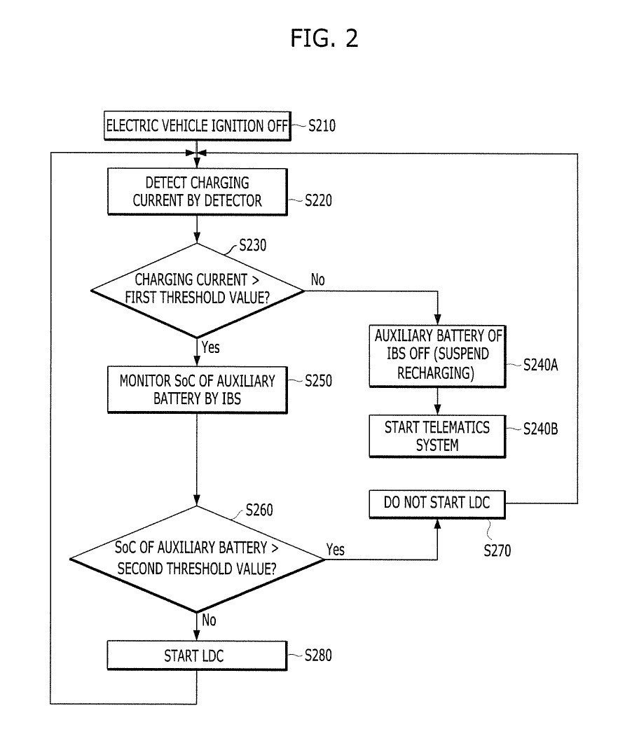

FIG. 2 is a flowchart illustrating an example of an operation of supplying power of the electric vehicle according to an embodiment of the present invention.

Referring to FIG. 2, in response to the external device being connected to the port 140 in a state in which the ignition of the electric vehicle is turned off in S210, a charging current may be detected by the detector 141 in S220. In this instance, the port 140 is supplied with power from the auxiliary battery 130.

When the detected charging current is greater than a first predetermined threshold value in S230, the detector 141 reports the information to the battery sensor 150 and monitors the SoC of the auxiliary battery 130 in S250.

When the SoC of the auxiliary battery 130 is less than or equal to a second predetermined threshold value in S260, the battery sensor 150 may start the power converter 120 or keep the power converter 120 on in S280. On the contrary, when the SoC of the auxiliary battery 130 is greater than the second predetermined threshold value, the battery sensor 150 does not start the power converter 120 or disables the power converter 120 in S270. This may include an operation of controlling the power converter 120 which is being started.

Meanwhile, when the detected charging current is lower than the first predetermined threshold value in S230, the battery sensor 150 may determine that it is unnecessary to recharge the connected device to suspend monitoring of the auxiliary battery 130 and deactivate the auxiliary battery 130 as necessary in S240A. S240A may be performed when the charging current becomes lower than the first threshold value in the detector 141 after the power converter 120 wakes up in response to recharging of the connected external device being started. In this case, the battery sensor 150 may inform the telematics communication unit 160 of completion of recharging through the event information, and the telematics communication unit 160 may report the information to a predetermined device or contact information at step S240B.

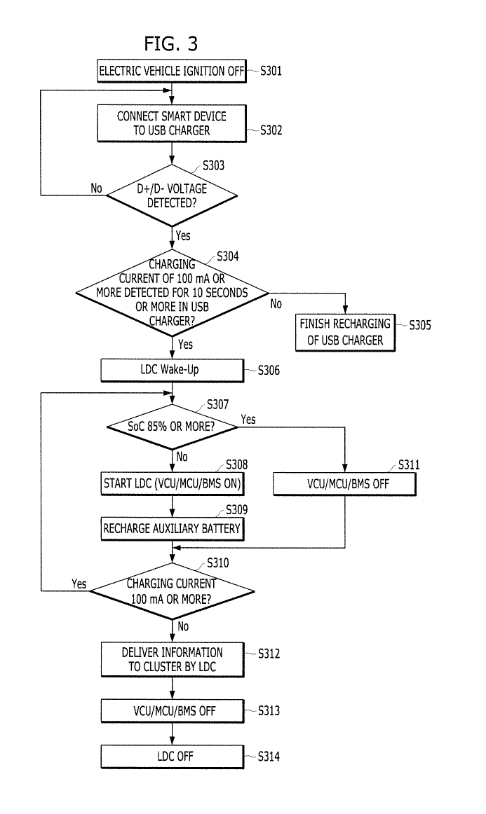

Hereinafter, a detailed description will be given of the operation of supplying power according to the present embodiment with reference to FIG. 3 by presuming a specific charging current value and a specific SoC value as examples when the port 140 corresponds to the USB port.

FIG. 3 is a flowchart illustrating an example of an operation of supplying power to a USB port of the electric vehicle according to an embodiment of the present invention.

In FIG. 3, it is presumed that the first threshold value corresponds to 100 mA, the second threshold value corresponds to 85%, and a smart device (for example, a smartphone) is connected to the USB port after the ignition of the electric vehicle is turned off.

Referring to FIG. 3, the smart device may be connected to the USB port 140 in S302 in a state in which the ignition of the electric vehicle is turned off in S301. When a D+/D− voltage is detected in the USB port, the detector 141 determines whether a charging current of 100 mA or more is detected for 10 seconds or more in the USE port in S304. When the condition of the charging current is not detected, the detector 141 determines that recharging of the connected smart device is completed in S305. When the condition of the charging current is detected, the detector 141 transmits a wake-up signal to the power converter 120 in S306. Thereafter, the battery sensor 150 monitors the SoC of the auxiliary battery 130 to determine whether the SoC is 85% or less in S307. When the SoC is 85% or less, the battery sensor 150 starts the power converter 120 or keeps the power converter 120 on in S308 such that the auxiliary battery 130 is recharged in S309. In this instance, a vehicle control unit (VCU), the MCU, and a battery management system (BMS) may be started together to start the power converter 120. Conversely, when the SoC is 85% or more, the VCU/MCU/BMS may not be started in S311.

When the charging current becomes 100 mA or less after recharging is started in S310, the detector 141 determines that recharging of the connected smart device is completed. Then, the power converter 120 may report that recharging is completed using a cluster, thereby visually informing the user that recharging is completed in S312. In addition, in response to the VCU/MCU/BMS being turned off in S313, the power converter 120, if being turned on, may be turned off in S314.

As described in the foregoing, when recharging is determined to be completed after being started, the battery sensor 150 may inform the telematics communication unit 160 that recharging is completed.

In summary, the present invention has advantages over the conventional art as described below.

A conventional USB recharging system for vehicles has a disadvantage that recharging may be performed only when the vehicle is being driven. Therefore, when a driving distance is short and thus a driving time is short, the smartphone may be insufficiently recharged. On the other hand, according to the present invention, even when starting of the electric vehicle is completed, the external device such as the smartphone, etc. may be recharged without concern that the auxiliary battery may be over discharged. Further, when recharging is completed, the information may be transmitted through the telematics system. Therefore, even when the user vacates the seat after recharging the tablet PC through the USB port of the vehicle, the user may conveniently verify whether recharging is completed through a message transmitted to the smartphone of the user through the telematics system.

The above-described time synchronization method may be configured by combining all or selectively some of the respective embodiments rather than restrictively applying the configurations and methods of the above embodiments such that the embodiments can be modified in various manners.

According to the present invention, it is possible to supply power to a particular port and thus to recharge a mobile device in an electric vehicle even when the ignition is turned off.

In particular, according to the present invention, power may be supplied from a main battery to an auxiliary battery according to an SoC of the auxiliary battery when power is supplied to a particular port through the auxiliary battery, and thus the auxiliary battery may be prevented from being discharged.

Effects that may be obtained from the present invention are not limited to the above-mentioned effects, and other effects not mentioned herein may be clearly understood by those skilled in the art from the above description.

What is claimed is:

1. A power supply apparatus of an electric vehicle, comprising:
a main battery;
an auxiliary battery;
a power converter for converting power from the main battery and recharging the auxiliary battery with the converted power;
a port for recharging a connected external device by power from the auxiliary battery when an ignition of the electric vehicle is turned off; and
a battery sensor for monitoring a state of charge (SoC) of the auxiliary battery and starting the power converter according to the SoC.

2. The power supply apparatus according to claim 1, wherein the port includes a detector for detecting charging power of the external device.

3. The power supply apparatus according to claim 2, wherein:
the detector is connected to the power converter, and
the detector transmits a wake-up signal to the power converter when the detected charging power is greater than or equal to a first threshold value.

4. The power supply apparatus according to claim 3, wherein the battery sensor starts the power converter when the SoC is less than or equal to a second threshold value after the power converter wakes up by the wake-up signal.

5. The power supply apparatus according to claim 4, wherein a vehicle control unit (VCU), a motor control unit (MCU), and a battery management system (EMS) are activated when the power converter is started.

6. The power supply apparatus according to claim 3, further comprising a telematics communication unit for transmitting a radio signal to an external device,
wherein the battery sensor informs the telematics communication unit that recharging is completed when the detected charging power decreases from a value greater than or equal to the first threshold to another value less than the first threshold value.

7. The power supply apparatus according to claim 6, wherein the telematics communication unit transmits a radio signal corresponding to the completion of recharging to a predetermined device or contact information.

8. The power supply apparatus according to claim 3, wherein the power converter informs a cluster that recharging of the connected external device is completed when the detected charging power decreases from a value greater than or equal to the first threshold value to another value less than the first threshold value.

9. The power supply apparatus according to claim 1, wherein the port includes a universal serial bus (USB) port.

10. The power supply apparatus according to claim 1, wherein the main battery has a greater voltage than a voltage of the auxiliary battery.

11. A method of supplying power of an electric vehicle, comprising:
detecting that an external device is connected to a port supplied with power through an auxiliary battery in a state in which an ignition of the electric vehicle is turned off;
detecting a charging current by a detector of the port;
monitoring a state of charge (SoC) of the auxiliary battery by a battery sensor when the detected charging current is greater than or equal to a first threshold value; and
starting a power converter, which recharges the auxiliary battery using power of a main battery, by the battery sensor according to the SoC.

12. The method according to claim 11, further comprising transmitting a wake-up signal to the power converter from the detector when the detected charging current is greater than or equal to a first threshold value,
wherein the detector is connected to the power converter.

13. The method according to claim 12, wherein the starting includes starting the power converter when the SoC is less than or equal to a second threshold value after the power converter wakes up by the wake-up signal.

14. The method according to claim 13, wherein the starting includes activating a VCU, an MCU, and a BMS.

15. The method according to claim 12, further comprising informing a telematics communication unit by the battery sensor that recharging is completed when the detected charging power decreases from a value greater than or equal to the first threshold value to another value less than the first threshold value.

16. The method according to claim 15, further comprising transmitting a radio signal corresponding to the completion of recharging to a predetermined device or contact information by the telematics communication unit.

17. The method according to claim 12, further comprising informing a cluster by the power converter that recharging of the connected external device is completed when the detected charging power decreases from a value greater than or equal to the first threshold value to another value less than the first threshold value.

18. The method according to claim 11, wherein the port includes a USB port.

19. The method according to claim 11, wherein the main battery has a greater voltage than a voltage of the auxiliary battery.

20. A battery sensor comprising:
a controller area network (CAN) transceiver for exchanging a signal with an external device;
a state of charge (SoC) sensor for detecting an SoC of an auxiliary battery; and
a controller for monitoring the SoC of the auxiliary battery when charging current information is received from a detector of a port when an ignition of an electric vehicle is turned off, and starting a power converter, which recharges the auxiliary battery using power of a main battery, according to the SoC of the auxiliary battery.
